(19) United States
(12) Patent Application Publication
(10) Pub. No.: US 2017/0274794 A1
(43) Pub. Date: Sep. 28, 2017

(54) CELL STATUS ESTIMATION DEVICE AND POWER SUPPLY DEVICE

(71) Applicant: Panasonic Intellectual Property Management Co., Ltd., Osaka (JP)

(72) Inventors: HIROSHI TENMYO, Osaka (JP); MUTSUHIKO TAKEDA, Kanagawa (JP); SHINICHI YUASA, Kyoto (JP)

(73) Assignee: Panasonic Intellectual Property Management Co., Ltd., Osaka (JP)

(21) Appl. No.: 15/504,058

(22) PCT Filed: Jan. 20, 2016
(86) PCT No.: PCT/JP2016/000264

§ 371 Date: Feb. 15, 2017

(30) Foreign Application Priority Data
Feb. 13, 2015 (JP) 2015-025964

(51) Int. Cl. B60L 11/18; G01R 31/36; B60W 10/26; H01M 10/48

(52) U.S. Cl. CPC B60L 11/1851; H01M 10/482; G01R 31/3648; G01R 31/361; B60W 10/26; G01R 31/3662

(57) ABSTRACT

A battery status estimation device includes an SOC determination unit for determining whether a charge rate of a battery should be estimated based on a full charge capacity or a dischargeable capacity of the battery, a full charge capacity estimation unit for estimating the full charge capacity, a discharge capacity estimation unit for estimating the dischargeable capacity, and a current integrated estimation unit for estimating the charge rate of the battery based on the full charge capacity or the dischargeable capacity.

### TECHNICAL FIELD

The present disclosure relates to a battery status estimation device and a power supply device.

### BACKGROUND ART

Hybrid electric vehicles (HEVs), plug-in hybrid electric vehicles (PHEVs), and electric vehicles (EVs) have been widely used in recent years. These vehicles are equipped with, as a key device, a secondary battery. Vehicular secondary batteries mainly used include nickel hydride batteries and lithium ion batteries.

Compared with lap-top PCs, cellular phones, and other similar devices, vehicular secondary batteries and large-scale power storage systems are required to rigorously be safely controlled and to effectively utilize battery capacities. As a prerequisite, a highly precise SOC (charge rate) estimation is required. Typical SOC estimation methods include an open circuit voltage (OCV) method and a current integration method (also referred to as a coulomb counting method) (for example, see PTL 1).

### CITATION LIST

### Patent Literature

PTL 1: Unexamined Japanese Patent Publication No. 2010-182579
PTL 2: Unexamined Japanese Patent Publication No. 2011-43513

### SUMMARY OF THE INVENTION

### Technical Problem

A battery stops discharging when SOC=0% or its voltage reaches a discharge stop voltage.

A battery in which a degree of degradation is smaller satisfies SOC 0% at a timing when a terminal voltage of the battery reaches a discharge stop voltage. As a battery degrades, an internal resistance of the battery increases. As the internal resistance of the battery increases, a voltage drop occurs, and thus the battery stops discharging. Even though the battery stops discharging due to a voltage drop, the battery itself has not yet fully been discharged and has a remaining capacity. Thus, SOC≠0% is observed.

For example, when a fuel meter of an electric vehicle or another vehicle or a fuel meter (capacity meter) of an electricity storage device such as a large-scale power storage system displays a value based on an SOC, even though the fuel meter displays a value based on a fact that SOC≠0%, a terminal voltage of a battery sometimes reaches a discharge stop voltage due to a voltage drop, and, as a result, the electric vehicle or another vehicle stops running.

PTL 2 describes a method for calculating a dischargeable capacity based on a device stop voltage of an electric load (external device), an ambient temperature of a secondary battery, and a discharge rate. In PTL 2, however, an occurrence of a voltage drop due to degradation of the secondary battery is not taken into account for calculating a dischargeable capacity of a battery.

The present disclosure has an object to provide a battery status estimation device and a power supply device for correcting an SOC in conformity to an actual discharge performance of a battery without interfering supplying electric power to a load.

### Solution to Problem

A battery status estimation device according to the present disclosure includes an SOC determination unit for determining whether a charge rate of a battery is estimated based on a full charge capacity or a dischargeable capacity of the battery, a full charge capacity estimation unit for estimating the full charge capacity, a discharge capacity estimation unit for estimating the dischargeable capacity, and a current integrated estimation unit for estimating the charge rate of the battery based on the full charge capacity or the dischargeable capacity.

### Advantageous Effects of Invention

According to the present disclosure, a battery status estimation device and a power supply device for correcting an SOC in conformity to an actual discharge performance of a battery without interfering supplying electric power to a load can be provided.

### BRIEF DESCRIPTION OF DRAWINGS

FIG. 1 is a view for describing a storage battery system according to an exemplary embodiment.

FIG. 2 is a view illustrating a configuration example of a battery status estimation device according to the exemplary embodiment.

FIG. 3 is a view illustrating a configuration example of a storage unit according to the exemplary embodiment.

FIG. 4 is a graph illustrating a relationship between a discharge section capacity and SOC_FULL during discharging.

FIG. 5 illustrates a temperature correction table and a current correction table according to the exemplary embodiment.

FIG. 6 is a conceptual graph illustrating a correspondence relationship between an FCC, a discharge rate, and a dischargeable capacity according to the exemplary embodiment.

FIG. 7 is a conceptual graph illustrating a relationship between a voltage drop, SOC_Full, and SOC_Usable.

FIG. 8 is a flowchart of an SOC correction process performed by the battery status estimation device according to the exemplary embodiment.

FIG. 9 is a flowchart of another SOC correction process performed by the battery status estimation device according to the exemplary embodiment.

### DESCRIPTION OF EMBODIMENT

An exemplary embodiment will now be described in detail with reference to the drawings. Some descriptions might be omitted for substantially identical configurations shown in the drawings to avoid duplication.

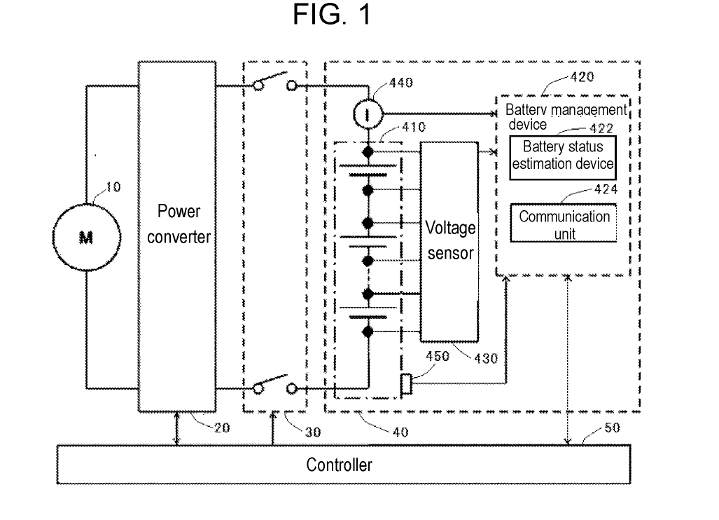

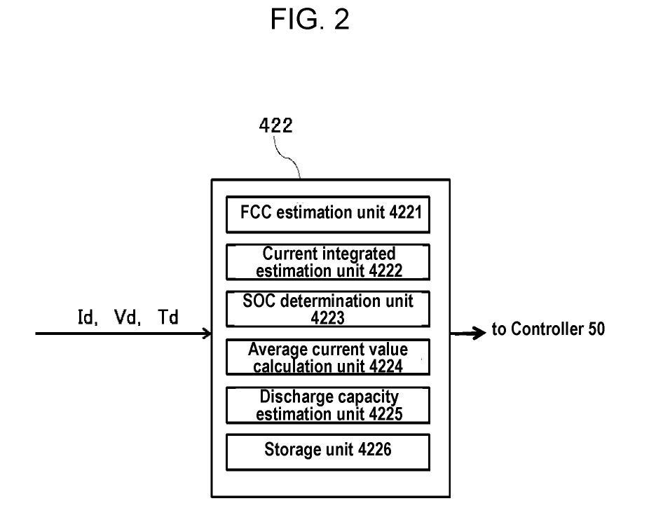

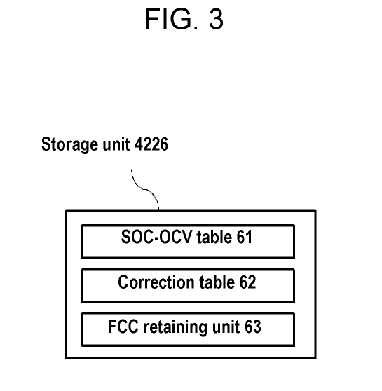

FIG. 1 is a view for describing storage battery system 40 according to the exemplary embodiment. FIG. 2 is a view illustrating a configuration example of battery status estimation device 422 according to the exemplary embodiment. FIG. 3 is a view illustrating a configuration example of storage unit 4226 according to the exemplary embodiment. This exemplary embodiment assumes that storage battery system 40 is mounted in a vehicle, such as an HEV, a PHEV, or an EV, to serve as a power supply. A configuration including storage battery system 40 and a fuel meter for displaying a remaining capacity of a battery is referred to as a power supply device.

Running motor 10 is, for example, a three-phase AC synchronous motor. Power converter 20 is coupled to storage battery system 40 via relay 30. At a time of power running, power converter 20 converts DC power supplied from storage battery system 40 into an alternating current, and supplies the alternating current to running motor 10. At a time of regeneration, power converter 20 converts AC power supplied from running motor 10 into DC power, and supplies the DC power to storage battery system 40.

Relay 30 is controlled to an open status or a closed status through a relay control signal sent from controller 50. In the closed status, relay 30 couples power converter 20 and storage battery system 40 to form a charging and discharging path. In the open status, relay 30 disconnects the charging and discharging path between power converter 20 and storage battery system 40.

Controller 50 electrically controls an entire vehicle. Based on an operation amount of an accelerator operated by a user, a vehicle speed, information from the power storage system, and other information, controller 50 sets a torque request value for running motor 10. Controller 50 controls power converter 20 so that running motor 10 operates in accordance with this torque request value. For example, as a torque request value increases, controller 50 accordingly controls power converter 20 so that further electric power is supplied to running motor 10 in conformity to an increased degree of the torque request value. As the torque request value reduces, controller 50 controls power converter 20 so that electric power generated by running motor 10 from deceleration energy as an energy source is supplied to storage battery system 40.

Storage battery system 40 includes battery module 410, battery management device 420, voltage sensor 430, current sensor 440, and temperature sensor 450.

Battery module 410 is configured by at least one battery (also referred to as a secondary battery). This exemplary embodiment assumes that a lithium ion secondary battery is used as a battery included in battery module 410. Although, in FIG. 1, battery module 410 is configured by a plurality of batteries coupled in series, battery module 410 may be configured by a single battery. A part or all of the batteries included in battery module 410 may be coupled in parallel to each other. In this exemplary embodiment, unless otherwise specified, a battery means a single battery.

Battery module 410 is coupled to power converter 20 via relay 30. When running motor 10 operates as a power supply source (at the time of regeneration), battery module 410 can accept the supplied charging electric power via power converter 20. When running motor 10 operates as a load (at the time of power running), battery module 410 can supply the discharging electric power via power converter 20.

Through external charging and power running/regeneration control performed by power converter 20, a battery in storage battery system 40 is charged and discharged. To avoid overcharging and overdischarging, controller 50 is required to precisely recognize an SOC of the battery. That is, charging and discharging of the battery are controlled by controller 50. An SOC of the battery, which is recognized by controller 50 to avoid overcharging and overdischarging, is represented by SOC_Full described later. Voltage sensor 430 detects voltage value Vd of a terminal voltage of each of the plurality of batteries configuring battery module 410 (a potential difference between a positive electrode and a negative electrode of each of the batteries). Voltage sensor 430 outputs detected voltage value Vd of each battery to battery management device 420.

Current sensor 440 is disposed between battery module 410 and power converter 20 to measure current value Id of a current flowing into battery module 410. Current sensor 440 outputs detected current value Id to battery management device 420.

Temperature sensor 450 detects temperature Td of battery module 410 (for example, a surface temperature of battery module 410). Battery module 410 outputs detected temperature Td to battery management device 420.

Battery management device 420 includes battery status estimation device 422 and communication unit 424. Battery status estimation device 422 uses battery status data including current value Id, voltage value Vd, and temperature Td to estimate a battery status such as a state of charge (SOC, also referred to as a charge rate).

Communication unit 424 sends information regarding the battery status such as the SOC estimated by battery status estimation device 422 to controller 50. Battery management device 420 and controller 50 are coupled via a network such as a controller area network (CAN).

Battery status estimation device 422 includes FCC estimation unit (also referred to as a full charge estimation unit) 4221, current integrated estimation unit 4222, SOC determination unit 4223, average current value calculation unit 4224, discharge capacity estimation unit 4225, and storage unit 4226.

Storage unit 4226 includes SOC-OCV table 61, correction table 62, and FCC retaining unit 63. Correction table 62 is a table describing correction factors used for an SOC correction process described later and/or a full charge capacity (FCC) correction process described later. FCC retaining unit 63 temporarily retains an FCC.

When a battery is charged or discharged and then the battery degrades, the battery might stop discharging when an SOC is at a lower value even though SOC≠0%. This is caused by a voltage drop due to an increased internal resistance in the battery because the battery is degraded. The battery that has stopped discharging has a remaining capacity because the battery has not yet fully been discharged due to the voltage drop. That is, a dischargeable capacity in a degraded battery is not full charge capacity FCC, but a dischargeable capacity obtained by subtracting a remaining capacity from full charge capacity FCC (also referred to as a discharge capacity, or a DC). A method for correcting an SOC so as to satisfy SOC≈0% at a timing when a battery stops discharging due to a voltage drop will now be described herein.

Current integrated estimation unit 4222 performs an integration with current value Id flowing into a battery, which is detected by current sensor 440, to estimate an SOC of the battery. Specifically, (Equation 1) or (Equation 2) shown below is used to estimate an SOC.

SOC_Full=SOC₀±(Q/FCC)×100 (Equation 1)

SOC_Usable=SOC₀−(Q/DC)×100 (Equation 2)

SOC₀ represents an SOC before charging and discharging start, Q represents a current integration value (Unit: Ah), FCC represents a full charge capacity, and DC represents a dischargeable capacity. A symbol “+” represents charging, while a symbol “−” represents discharging.

SOC_Full represents an SOC estimated using a full charge capacity. SOC_Usable represents an SOC estimated using a dischargeable capacity.

A dischargeable capacity is calculated with an FCC and a discharge rate (Unit: C).

FCC estimation unit 4221 estimates an FCC of a battery based on a value of change in SOC_FULL, which is estimated by current integrated estimation unit 4222, and a current integration value in a period required for the change. An FCC can be estimated from (Equation 3) shown below.

FCC=(Qt/ΔSOC)×100 (Equation 3)

ΔSOC represents a value of change in SOC_FULL, while Qt represents a section capacity (Unit: Ah) required for ΔSOC. Hereinafter, a section capacity during discharging is referred to as a discharge section capacity, while a section capacity during charging is referred to as a charge section capacity.

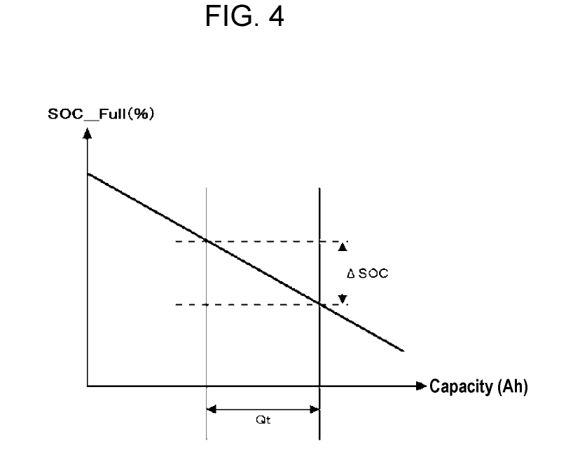

FIG. 4 is a graph illustrating a relationship between a discharge section capacity and SOC_FULL. As a discharge section capacity increases, a value of SOC_FULL reduces. In contrast, during charging, as a charge section capacity increases, a value of SOC_FULL increases. When SOC_FULL estimated by current integrated estimation unit 4222 lowers by a set value (for example, 10%), FCC estimation unit 4221 identifies a discharge section capacity in a section required for a change to estimate an FCC using (Equation 3) shown above. The discharge section capacity can be identified with a current integration value. With an FCC to newly be estimated along with an estimation of the FCC, FCC estimation unit 4221 updates an FCC retained by FCC retaining unit 63.

When estimating an FCC, section capacity Qt may be corrected. For example, a temperature correction and/or a current correction may be performed for section capacity Qt calculated through a time integration of a detected current value. FCC estimation unit 4221 calculates section capacity Qt′ after the correction using (Equation 4) and (Equation 5) shown below.

Qt′=Qt×αt (Equation 4)

Qt′=Qt×αi (Equation 5)

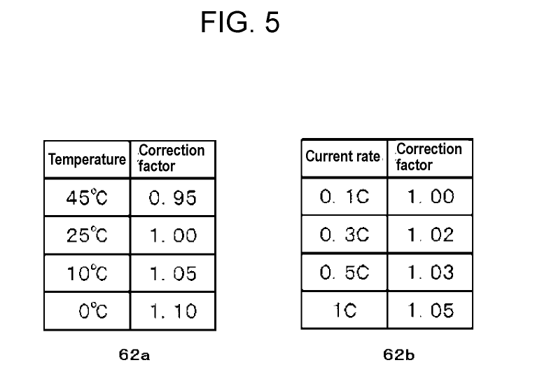

A symbol “αt” represents a temperature correction factor, while a symbol “αi” represents a current correction factor. FIG. 5 illustrates temperature correction table 62a and current correction table 62b. Temperature correction table 62a and current correction table 62b are data included in correction table 62. Temperature correction table 62a is a table describing a correspondence relationship between temperature Td to be detected by temperature sensor 450 and temperature correction factor αt. Current correction table 62b is a table describing a correspondence relationship between current value Id to be detected by current sensor 440 and current correction factor αi.

Based on detected temperature Td, FCC estimation unit 4221 refers to temperature correction table 62a to identify temperature correction factor αt. Based on detected current value Id, FCC estimation unit 4221 refers to current correction table 62b to identify current correction factor αi. The two correction factors may be integrated into section capacity Qt in any order.

Average current value calculation unit 4224 calculates an average current value when SOC_FULL changes by a set value to calculate a discharge rate (C) in a period of the change.

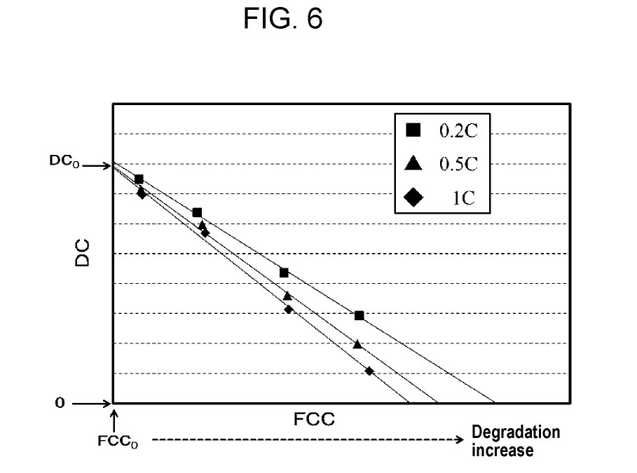

Based on the updated FCC and the calculated discharge rate (C), discharge capacity estimation unit 4225 estimates a dischargeable capacity. Here, FIG. 6 is a conceptual graph illustrating a correspondence relationship between an FCC, a discharge rate (C), and a dischargeable capacity. When discharge capacity estimation unit 4225 estimates a dischargeable capacity, discharge capacity estimation unit 4225 refers to the conceptual graph shown in FIG. 6 to verify an updated FCC and a discharge rate (C) to estimate a dischargeable capacity. The conceptual graph shown in FIG. 6 is stored in storage unit 4226.

In the conceptual graph shown in FIG. 6, axis X shows FCC, while axis Y shows dischargeable capacity, where discharge rates (C) are plotted in the graph. An intersection of axis X and axis Y is represented by (X, Y)=(FCC₀, 0). An intersection of axis Y and discharge rate is represented by (X, Y)≈(FCC₀, DC₀).

(X, Y)≈(FCC₀, DC₀) represents that a battery is not degraded. FCC₀ represents a full charge capacity in a state that the battery has not yet been degraded. DC₀ represents a dischargeable capacity in a state that the battery has not yet been degraded. In axis X, as a value increases rightward, the battery degrades. In axis Y, as a value increases downward, the battery degrades. The conceptual graph shown in FIG. 6 represents that, in a degradation status, as the battery discharges electricity at a higher discharge rate (C), a dischargeable capacity reduces. The conceptual graph shown in FIG. 6 represents that, as the battery discharges electricity at a lower discharge rate (C), a dischargeable capacity increases in a status where the battery is further degraded.

The conceptual graph shown in FIG. 6 is generated, through a preliminarily experiment or simulation, from data on dischargeable capacities and FCCs obtained in a course of gradual degradation of a secondary battery from an initial status. To perform a preliminarily experiment or simulation, secondary batteries discharge electricity at a plurality of discharge rates to obtain FCCs and dischargeable capacities of the secondary batteries degraded at various degrees.

Current integrated estimation unit 4222 estimates an SOC of a battery using (Equation 1) or (Equation 2) shown above. If an expected effect of degradation in a battery is significant, current integrated estimation unit 4222 estimates SOC_Usable as an SOC of the battery. A term “to correct an SOC” means that “SOC_Usable is estimated as an SOC of a battery.”

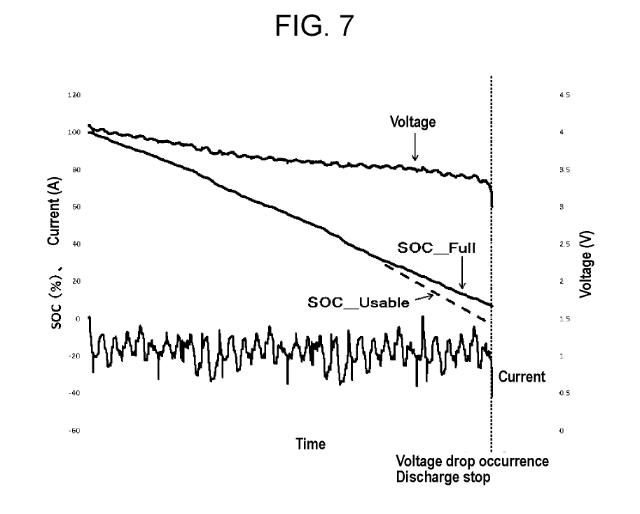

FIG. 7 is a conceptual graph illustrating a relationship between a voltage drop, SOC_Full, and SOC_Usable. At a timing when a voltage drop occurs and a battery stops discharging, SOC_Full≠0% and SOC_Usable≈0% are observed.

SOC determination unit 4223 determines whether an SOC needs to be corrected.

For example, SOC determination unit 4223 may be configured to make a determination such that, while a battery is discharging, if a difference between SOC_Full calculated through (Equation 1) shown above and SOC_OCV estimated through an OCV method is smaller than a predetermined value, SOC_Full is used as an SOC, while, if a difference between SOC_Full and SOC_OCV is greater than the predetermined value, SOC_Usable is used as the SOC. With the OCV method, an open circuit voltage (OCV) of a battery is estimated, and, by referring to SOC-OCV table 61 stored in storage unit 4226, an SOC corresponding to the estimated OCV is identified. SOC-OCV table 61 is a table describing a relationship between an SOC of a battery and an open circuit voltage (OCV) of the battery. SOC-OCV table 61 is generated, through a preliminarily experiment or simulation, from data on SOCs and OCVs obtained when a battery cell in a status where a charge rate is 0% is gradually charged. SOC-OCV table 61 may be generated, through a preliminarily experiment or simulation, from data on SOCs and OCVs obtained when a battery cell in a status where a charge rate is 100% gradually discharges electricity.

As another method performed by SOC determination unit 4223 to make a determination, while a battery is discharging, if SOC_Full calculated through (Equation 1) shown above lowers to a value equal to or below a predetermined value (for example, SOC_Full is 30% or lower) and the battery keeps discharging, a determination may be made such that SOC_Usable is used as an SOC.

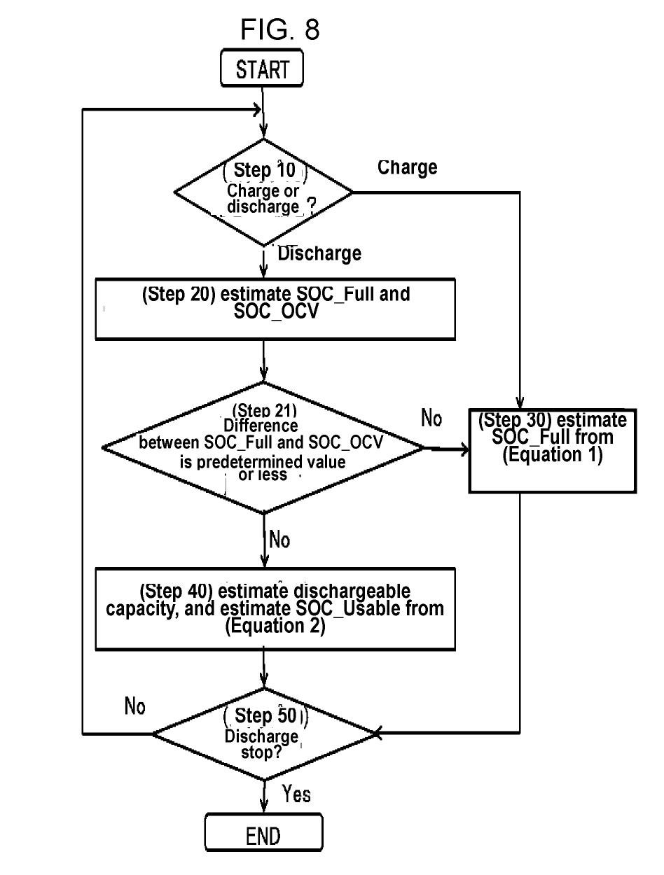

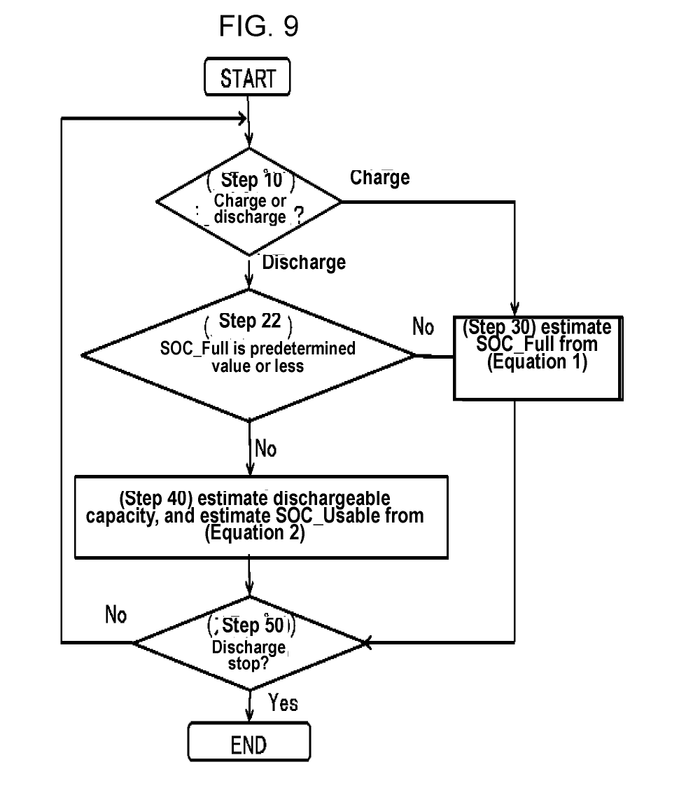

Next, an SOC correction process performed by battery status estimation device 422 configured as described above will now be described with reference to the flowcharts shown in FIGS. 8 and 9. FIG. 8 describes that a determination to be made by SOC determination unit 4223 of whether SOC_Usable is used as an SOC is made through a determination of whether a difference between SOC_Full and SOC_OCV is equal to or above a predetermined value. FIG. 9 describes that a determination to be made by SOC determination unit 4223 of whether SOC_Usable is used as an SOC is made through a determination of whether SOC_Full lowers to a value equal to or below a predetermined value.

A correction of an SOC will now be described with reference to the flowchart shown in FIG. 8.

Controller 50 controls charging and discharging of a battery (step 1).

When the battery is charged, current integrated estimation unit 4222 estimates SOC_Full from (Equation 1) to estimate that the estimated SOC_Full is an SOC of the battery (step 30).

When the battery is discharged, SOC_Full and SOC_OCV are estimated (step 20). SOC determination unit 4223 calculates a difference between SOC_Full and SOC_OCV (step 21). If the difference between SOC_Full and SOC_OCV exceeds a predetermined value, SOC determination unit 4223 determines to estimate that SOC_Usable is an SOC of the battery (step 21). If the difference between SOC_Full and SOC_OCV is equal to or below the predetermined value, SOC determination unit 4223 determines to estimate that SOC_Full is the SOC of the battery (step 21).

When SOC determination unit 4223 determines to estimate that SOC_Full is the SOC of the battery, current integrated estimation unit 4222 estimates SOC_Full from (Equation 1) to estimate that the estimated SOC_Full is the SOC of the battery (step 30).

When SOC determination unit 4223 determines to estimate that SOC_Usable is the SOC of the battery, discharge capacity estimation unit 4225 estimates a dischargeable capacity (step 40). Current integrated estimation unit 4222 then estimates SOC_Usable from (Equation 2) to estimate that the estimated SOC_Usable is the SOC of the battery (step 40).

After step 30 or step 40, when a terminal voltage of the battery reaches a discharge stop voltage, the battery stops discharging (step 50). After step 30 or step 40, when the terminal voltage of the battery does not reach the discharge stop voltage, the process returns to step 10 (step 50). Controller 50 determines whether the terminal voltage of the battery reaches the discharge stop voltage.

In an SOC correction process illustrated by the flowchart of FIG. 9, when SOC_Full is equal to or below a predetermined value (for example, 30% or lower), SOC determination unit 4223 determines to estimate that SOC_Usable is an SOC of a battery (step 22). In the process in accordance with the flowchart shown in FIG. 9, an SOC correction process similar to the SOC correction process illustrated by the flowchart of FIG. 8 is performed, excluding a determination to be made by SOC determination unit 4223.

A calculation of SOC_Usable performed by current integrated estimation unit 4222 and an estimation of a dischargeable capacity performed by discharge capacity estimation unit 4225 may be made, through step 21 or 22, only when an estimation that SOC_Usable is an SOC is determined. An estimation that SOC_Usable is an SOC is, for example, made in a case when a fuel meter displays a remaining capacity of a battery based on an SOC. Since SOC_Usable is a value determined in consideration of a voltage reaching a discharge stop voltage due to a voltage drop, by estimating that SOC_Usable is an SOC, a remaining capacity of a battery can be adjusted such that a fuel meter displays zero at a timing when the voltage reaches the discharge stop voltage.

In addition to the SOC correction processes illustrated by the flowcharts shown in FIGS. 8 and 9, a calculation of SOC_Full performed by current integrated estimation unit 4222 and an estimation of an FCC performed by FCC estimation unit 4221 are periodically performed at a predetermined interval during charging and discharging of a battery. This allows controller 50 to use SOC_Full regarded as an actual charge rate to control charging and discharging of the battery in a range where neither overcharging nor overdischarging occurs.

In the above exemplary embodiment, a battery status estimation device for a battery used as a power supply for driving a motor in an electric vehicle or the like has been exemplified. However, a correction of an SOC according to the present disclosure can be performed for a battery status estimation device for a battery used as a home or industrial power supply.

### INDUSTRIAL APPLICABILITY

A battery status estimation device and a power supply device according to the present disclosure are useful for power supplies for driving motors in electric vehicles and other vehicles, and for back-up power supplies.

### REFERENCE MARKS IN THE DRAWINGS

10: running motor
20: power converter
30: relay
40: storage battery system
410: battery module
420: battery management device
422: battery status estimation device
4221: FCC estimation unit
4222: current integrated estimation unit
4223: SOC determination unit
4224: average current value calculation unit
4225: discharge capacity estimation unit
4226: storage unit
424: communication unit
430: voltage sensor
440: current sensor
450: temperature sensor
50: controller
61: SOC-OCV table
62: correction table
62a: temperature correction table
62b: current correction table
63: FCC retaining unit

1. A battery status estimation device for estimating a charge rate of a battery, the battery status estimation device comprising:
an SOC determination unit for determining whether the charge rate of the battery is estimated based on a full charge capacity or a dischargeable capacity of the battery;
a full charge capacity estimation unit for estimating the full charge capacity;
a discharge capacity estimation unit for estimating the dischargeable capacity; and
a current integrated estimation unit for estimating the charge rate of the battery based on the full charge capacity or the dischargeable capacity.

2. The battery status estimation device according to claim 1, wherein the SOC determination unit determines that, while the battery is discharged, when the charge rate of the battery estimated based on the full charge capacity lowers to a value equal to or below a predetermined value, the charge rate of the battery is estimated based on the dischargeable capacity.

3. The battery status estimation device according to claim 1, wherein the SOC determination unit calculates, while the battery is discharged, a difference between the charge rate of the battery estimated based on the full charge capacity and a charge rate estimated based on an open circuit voltage of the battery, and determines that, when the difference exceeds a predetermined value, the charge rate of the battery is estimated based on the dischargeable capacity.

4. The battery status estimation device according to claim 1, wherein the discharge capacity estimation unit estimates the dischargeable capacity, based on the full charge capacity estimated by the full charge capacity estimation unit and a discharge rate of the battery.

5. A power supply device comprising:
the battery status estimation device according to claim 1; and
a fuel meter,
wherein the fuel meter displays a remaining capacity of a battery based on a charge rate of the battery estimated by the battery status estimation device.

6. The battery status estimation device according to claim 2, wherein the discharge capacity estimation unit estimates the dischargeable capacity, based on the full charge capacity estimated by the full charge capacity estimation unit and a discharge rate of the battery.

7. The battery status estimation device according to claim 3, wherein the discharge capacity estimation unit estimates the dischargeable capacity, based on the full charge capacity estimated by the full charge capacity estimation unit and a discharge rate of the battery.

8. A power supply device comprising:
the battery status estimation device according to claim 2; and
a fuel meter,
wherein the fuel meter displays a remaining capacity of a battery based on a charge rate of the battery estimated by the battery status estimation device.

9. A power supply device comprising:
the battery status estimation device according to claim 3; and
a fuel meter,
wherein the fuel meter displays a remaining capacity of a battery based on a charge rate of the battery estimated by the battery status estimation device.

10. A power supply device comprising:
the battery status estimation device according to claim 4; and
a fuel meter,
wherein the fuel meter displays a remaining capacity of a battery based on a charge rate of the battery estimated by the battery status estimation device.
